(19) United States
(12) Patent Application Publication
(10) Pub. No.: US 2019/0027693 A1
(43) Pub. Date: Jan. 24, 2019

(54) LIGHT EMITTING COMPOUNDS

(71) Applicant: UNIVERSITY COURT OF THE UNIVERSITY OF ST ANDREWS, ST ANDREWS (GB)

(72) Inventors: Eli ZYSMAN-COLMAN, ST. ANDREWS, FIFE (GB); Michael Yin WONG, ST. ANDREWS, FIFE (GB)

(21) Appl. No.: 16/067,390

(22) PCT Filed: Dec. 8, 2016
(86) PCT No.: PCT/GB2016/053858

§ 371 Date: Jun. 29, 2018

(30) Foreign Application Priority Data
Dec. 29, 2015 (GB) 1523037.8

(51) Int. Cl. H01L 51/00; H01L 51/50; C09K 11/06

(52) U.S. Cl. CPC H01L 51/0052; H01L 51/006; C09K 11/06; H01L 51/5032; H01L 51/5016; H01L 51/0072

(57) ABSTRACT

Organic thermally activated delayed fluorescence (TADF) species according to Formula I are described. The species have donor (D) and acceptor (A) moieties bonded to a ring system (Q). Q is an unsaturated carbocyclic or heterocyclic ring system including at least two rings fused together. The ring system Q may include at least one polyunsaturated ring, typically an aromatic or heteroaromatic ring. A polyunsaturated ring includes at least two double bonds. The ring system Q may include at least one benzene ring fused to at least one other ring. Both the at least two rings fused together in ring system Q may be aromatic and/or heteroaromatic rings. The ring system Q may be an annelated benzene or annelated heteroarene ring system.

### FIELD OF THE INVENTION

The invention relates to organic thermally activated delayed fluorescence (TADF) species. They can find use as emitter material in light emitting devices, such as Organic light-emitting diodes (OLEDs) and Light Emitting Electrochemical Cells (LEECs).

### BACKGROUND TO THE INVENTION

Organic light-emitting diodes (OLEDs) are regarded as the current state-of-the-art in display technology and they have attracted and continue to attract intense research interest from both industry and academia. OLEDs also hold great promise in diffuse lighting technology due to their efficiency and low power consumption. This latter point is particularly germane as lighting current accounts for approximately 20% of electricity consumption globally corresponding to 1900 Mt of equivalent CO₂ emissions in 2012. In this context, highly efficient and inexpensive OLEDs are required.

In electroluminescence devices, charge recombination generates both singlet and triplet excitons in a 1:3 ratio. The latter are lost as heat when fluorescent emitters are used in OLEDs due to their excessively long phosphorescence lifetime. Organometallic phosphorescent emitters were introduced at the turn of the 21st century to address the issue of inefficient charge recombination.

These metal centres in these emitters promote strong spin-orbit coupling (SOC) and thus efficient intersystem crossing (ISC) so that the phosphorescence lifetime is significantly reduced to a usable microsecond regime. Emission from both singlet and triplet excitons are therefore accessible in these materials. A major drawback to their use is the cost and rarity of metals employed, such as iridium and platinum.

Additionally, though performance of red and green phosphorescent emitters meets industrial requirements, the stability and brightness of blue phosphorescent OLEDs remains problematic.

Recently, Adachi and co-workers have successfully employed small molecule organic emitters in OLEDs whose emission results from a mechanism called thermally activated delayed fluorescence (TADF). (Ref 1) Unlike the traditional fluorescent emitters, TADF emitters are capable of recruiting both singlet and triplet excitons in OLEDs. This is possible as these compounds possess very small exchange energies (ΔE_{ST}), which facilitate reverse intersystem crossing (RISC) in which singlet excitons are generated from triplet excitons.

In order to obtain to minimize ΔE_{ST}, the molecular design of the TADF emitter requires that the highest occupied molecular orbital (HOMO) must be spatially well separated from the lowest unoccupied molecular orbital (LUMO). One way to accomplish this is to install a large torsion between donor (HOMO) and acceptor (LUMO) moieties in the molecule. In most TADF emitter design a phenyl group (benzene ring) serves as the bridge between donor and acceptor units.

### DESCRIPTION OF THE INVENTION

According to a first aspect the present invention provides an organic thermally activated delayed fluorescence (TADF) species according to formula I:

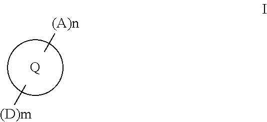

wherein;
Q is an unsaturated carbocyclic or heterocyclic ring system including at least two rings fused together;
each A is an acceptor moiety;
each D is a donor moiety; and
n and m are at least 1.

According to a second aspect the present invention also provides a light emitting device comprising the organic thermally activated delayed fluorescence (TADF) species as emitter material. The light emitting device may be an OLED or a LEEC (light emitting electrochemical cell).

Q is an unsaturated carbocyclic or heterocyclic ring system including at least two rings fused together. The ring system Q may include at least one polyunsaturated ring, typically an aromatic or heteroaromatic ring. A polyunsaturated ring includes at least two double bonds. The ring system Q may include at least one benzene ring fused to at least one other ring. Both the at least two rings fused together in ring system Q may be aromatic and/or heteroaromatic rings. The ring system Q may be an annelated benzene or annelated heteroarene ring system.

The donor (D) and acceptor (A) moieties are bonded to bridging ring system Q. They are linked but spaced apart from each other by the bridging ring system Q. The number of D and A groups may be the same (m=n) or may be different (m≠n), to adjust photo physical behaviour. Both m and n are at least one. There is no particular upper limit to the number of (D) and acceptor (A) moieties, but typically from 1 to 5 or even from 1 to 3 of each may be employed. By making use of a fused ring system, containing at least two fused rings, a number of advantages may be obtained. The ring systems employed may be provided with different unsaturation and/or heteroatoms to adjust photo physical behaviour. The positioning of donor and acceptor moieties on the ring system may be adjusted to alter the photo physical behaviour of the molecule more readily than if just a phenyl ring is employed. The presence of at least two rings also allows more scope for positioning of substituents both (D) and acceptor (A) moieties and others, if desired.

Donor (D) and acceptor (A) moieties may be positioned on the same ring, for example in para positions on a benzene ring. Alternatively, donor (D) and acceptor (A) moieties may be positioned on different rings, for example on different benzene rings of ring system Q. Where more than one donor moiety is employed they may be the same or different. Where more than one acceptor moiety is employed they may be the same or different.

Donor (D) and acceptor (A) moieties may be of the types already employed in conventional TADF molecules.

Acceptor moieties may be selected from the group consisting of: cyano (—CN), ketone, esters, amides, aldehydes, sulfones, sulfoxides, phosphine oxides ketones, esters, amides, aldehydes, sulfones, sulfoxides, phosphine oxides and substituted and unsubstituted 1,3,5 triazine and 1,3,4 oxadiazole moieties. Other examples of acceptor moieties can include substituted or unsubstituted pyridine, pyrimidine, pyrazine and 1,2,4-triazoles. In general electron poor heterocycles, for example electron poor 5 and 6 membered heterocycles, can find use as acceptor moieties.

For example ketone, ester, amide, aldehyde, sulfone, sulfoxide and phosphine oxides may be attached to ring system Q as shown in Scheme 1 below. —B represents the bonding position to ring system Q of these acceptor moieties A.

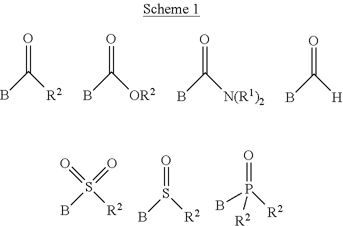

In Scheme 1, each —R² may be, independently for each occurrence, selected from the group consisting of: a substituted or unsubstituted primary, secondary or tertiary alkyl, that may be cyclic and may be unsaturated (for example C1-C10 or even C1-C4). In Scheme 1, each group R1 on the amide nitrogen may be, independently for each occurrence, selected from the group consisting of: —H, substituted or unsubstituted primary, secondary or tertiary alkyl, that may be cyclic and may be unsaturated (for example C1-C10 or even C1-C4); substituted or unsubstituted aryl or heteroaryl, (for example substituted or unsubstituted phenyl) and the like.

Other heterocycles may be employed as acceptor moieties A, such as substituted pyrrole and furan (attached via carbon to the ring system Q)

Examples of 1,3,5 triazine moieties and 1,3,4 oxadiazole moieties include those of formulas II, III and IIIa.

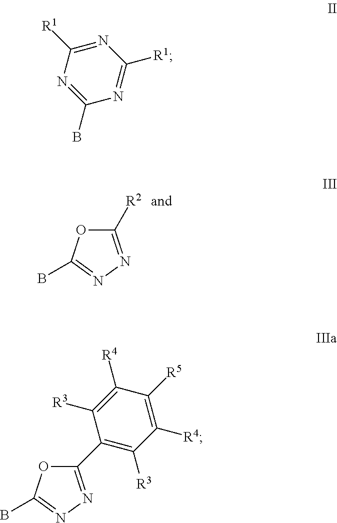

wherein —B represents the bonding position to ring system Q;
—R² represents a substituted or unsubstituted primary, secondary or tertiary alkyl, that may be cyclic and may be unsaturated (for example C1-C10 or even C1-C4); and wherein groups R¹, R³, R⁴ and R⁵ are, independently for each occurrence selected from the group consisting of :
—H, substituted or unsubstituted primary, secondary or tertiary alkyl, that may be cyclic and may be unsaturated (for example C1-C10 or even C1-C4); substituted or unsubstituted aryl or heteroaryl, —CF₃, —OMe, —SF₅, —NO₂, halo (e.g. fluoro, chloro, bromo and iodo), aryl hydroxy, amino, alkoxy, alkylthio, carboxy, cyano, thio, formyl, ester, acyl, thioacyl, amido, sulfonamido, carbamate, phosphine oxide, phosphine sulfide and the like.

Conveniently, 1,3,4 oxadiazole acceptor moieties can be formed by reaction of a nitrile containing TADF species. Reaction with azide produces a tetrazole which in turn reacts with an appropriate acid chloride to provide the oxadiazole. More generally heterocycles as acceptor moieties may be attached to ring system Q by cross-coupling or other types of substitution reactions and may include further manipulation to obtain the desired final product. Other known procedures such as condensation reactions maybe used to build acceptor moiety heterocyclic rings.

Where the groups R¹, R², R³, R⁴ and R⁵ (or any other groups provided in structures discussed herein), are described as substituted they may be independently substituted for each occurrence. For example once, twice, or three times, e.g. once, i.e. formally replacing one or more hydrogen atoms with substituents such as halo (e.g. fluoro, chloro, bromo and iodo), —SF₅, —CF₃, —OMe, —NO₂, substituted or unsubstituted primary, secondary or tertiary alkyl, that may be cyclic and may be unsaturated (for example C1-C10 or even C1-C4); substituted or unsubstituted aryl or heteroaryl, aryl hydroxy, amino, alkoxy, alkylthio, carboxy, cyano, thio, formyl, ester, acyl, thioacyl, amido, sulfonamido, carbamate, phosphine oxide, phosphine sulphide and the like. Where the substituent is amino it may be NH₂, NHR or NR₂, where the substituents R on the nitrogen may be alkyl, aryl or heteroaryl (for example substituted or unsubstituted C1-C20 or even C1-C10).

By aryl is meant herein a radical formed formally by abstraction of a hydrogen atom from an aromatic compound. As known to those skilled in the art, heteroaryl moieties are a subset of aryl moieties that comprise one or more heteroatoms, typically O, N or S, in place of one or more carbon atoms and any hydrogen atoms attached thereto. Exemplary aryl substituents, for example, include phenyl or naphthyl that may be substituted. Exemplary heteroaryl substituents, for example, include pyridinyl, furanyl, pyrrolyl and pyrimidinyl.

Further examples of heteroaromatic rings include pyridazinyl (in which 2 nitrogen atoms are adjacent in an aromatic 6-membered ring); pyrazinyl (in which 2 nitrogens are 1,4-disposed in a 6-membered aromatic ring); pyrimidinyl (in which 2 nitrogen atoms are 1,3-disposed in a 6-membered aromatic ring); or 1,3,5-triazinyl (in which 3 nitrogen atoms are 1,3,5-disposed in a 6-membered aromatic ring).

Where the group R¹, R², R³, R⁴ and R⁵ (or any of the groups provided in structures discussed herein), includes one or more rings they may be cycloalkyl. They may be for example cyclohexyl or cyclopentyl rings. The cyclohexyl or cyclopentyl groups if present may be saturated or unsaturated and may be substituted as described above.

Donor moieties D may be selected from:

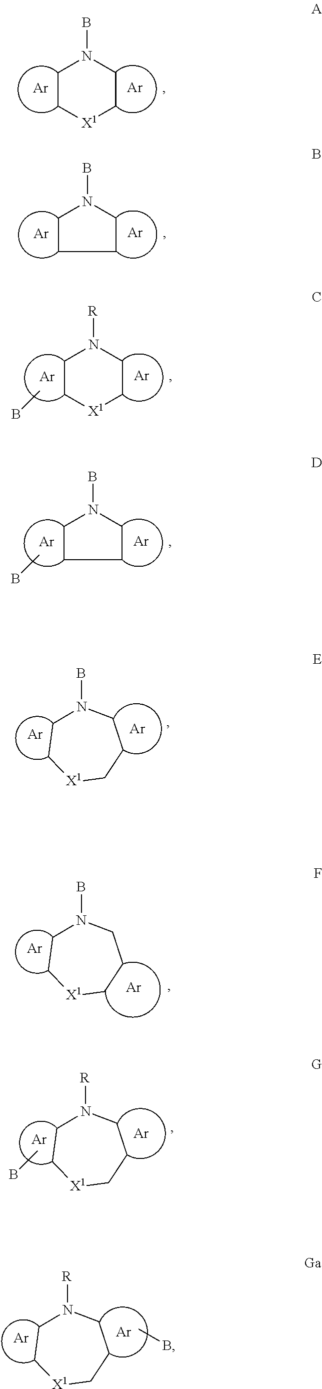

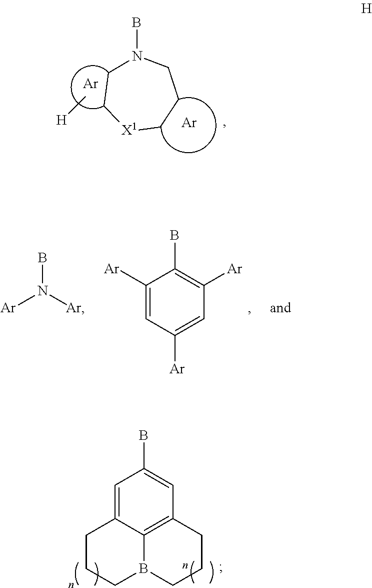

wherein —B represents the bonding position to ring system Q, that is para to the nitrogen in structures C, D, G, Ga and H;
X¹ is selected from the group consisting of O, S, NR, SiR₂, PR and CR₂; each R is independently selected from the group consisting of —H, alkyl, aryl or heteroaryl (for example substituted or unsubstituted C1-C20 or even C1-C10 alkyl);
each Ar is independently for each occurrence selected from the group consisting of substituted or unsubstituted aryl or heteroaryl; and

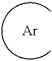

represents, independently for each occurrence a substituted or unsubstituted aryl or heteroaryl ring fused to the central ring of structures A, B, C, D, E, F, G, Ga or H; for example a five or a six membered substituted or unsubstituted aryl or heteroaryl ring; and
n ( ) indicates the optional presence of saturated —CH₂— groups in the rings annelated to the benzene ring, wherein n is independently for each occurrence, 0, 1, or 2.

Substituents on —Ar and

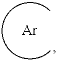

where present can include phosphine oxide or phosphine sulphide, to moderate the donor properties.

Phosphine oxide or phosphine sulphide may be used as acceptor moieties, or part of acceptor moieties (substituents on acceptor moieties) in the structure of a TADF molecule, such as the TADF compounds described herein.

Where used as a substituent on a donor moiety D as described herein, phosphine oxide or phosphine sulphide acts to moderate the character of the donor and can therefore alter the photo physical behaviour of a TADF compound, for example resulting in a change in colour and or intensity of emission.

Where a substituent described herein is phosphine oxide or phosphine sulphide it may be selected from the group consisting of:

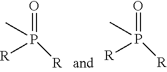

where the substituents R on the phosphorus may be substituted or unsubstituted alkyl, aryl or heteroaryl (for example substituted or unsubstituted C1-C20 or even C1-C10).

Thus substituents:

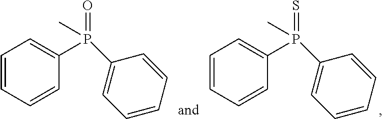

or substituents where one or both phenyl groups are substituted, are contemplated for both acceptor and donor moieties.

Phosphine oxide and phosphine sulphide substituents may be introduced, for example, in accordance with the Scheme below which illustrates substitution on carbazole, a typical donor moiety:

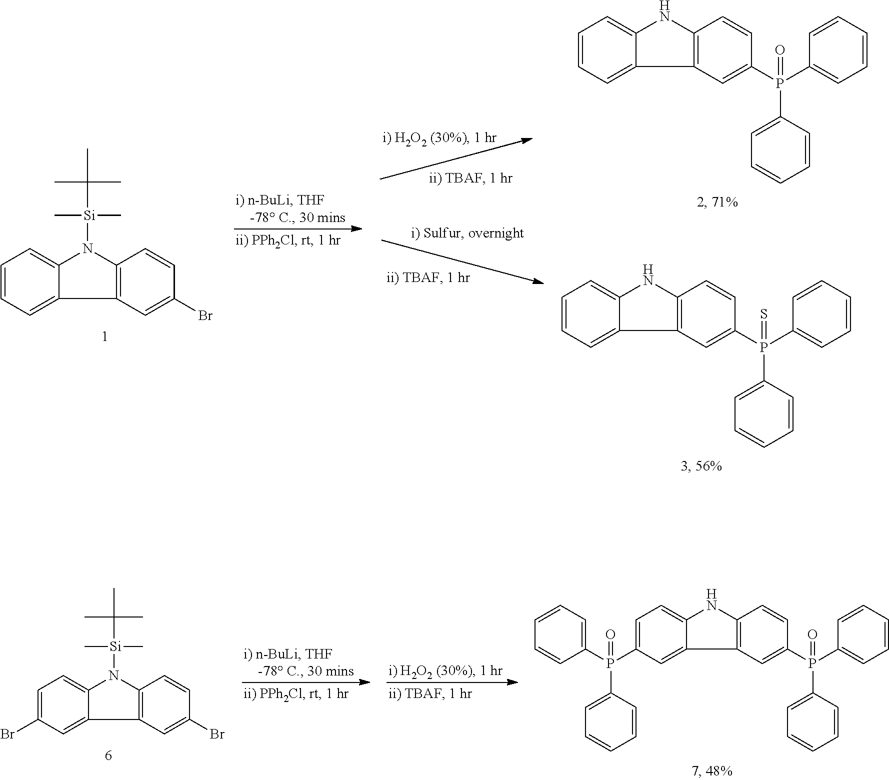 [SMILES: CC(C)(C)[Si](C)(C)n1c2ccccc2c2cc(Br)ccc21 ; S=P(c1ccccc1)(c1ccccc1)c1ccc2[nH]c3ccccc3c2c1 ; O=P(c1ccccc1)(c1ccccc1)c1ccc2[nH]c3ccccc3c2c1 ; CC(C)(C)[Si](C)(C)n1c2ccc(Br)cc2c2cc(Br)ccc21 ; O=P(c1ccccc1)(c1ccccc1)c1ccc2[nH]c3ccc(P(=O)(c4ccccc4)c4ccccc4)cc3c2c1]

The saturated rings annelated to the benzene ring in the structure:

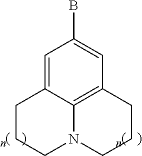

may be five six or seven membered rings. Typically they may be six membered, i.e. the juliolidine structure, where n is 1:

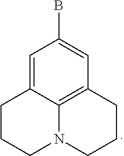

Thus donor moieties may be selected from the group consisting of substituted and unsubstituted carbazole, diphenylamine, phenothiazine, phenoxazine, phenazine, and dihydroacridine moieties. In donor moieties substituents on the ring systems may all be H. The donor moieties may be selected from the group consisting of:

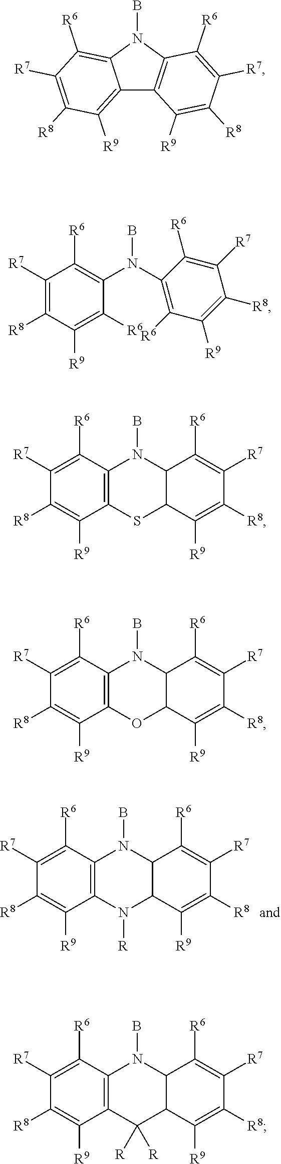

wherein —B represents the bonding position to ring system Q;
each group R⁶, R⁷, R⁸ and R⁹ is, independently for each occurrence, selected from the group consisting of —H, substituted or unsubstituted primary, secondary or tertiary alkyl, that may be cyclic and may be unsaturated (for example C1-C10 or even C1-C4); substituted or unsubstituted aryl or heteroaryl, —CF₃, —OMe, —SF₅, —NO₂, halo (e.g. fluoro, chloro, bromo and iodo), aryl, aryl hydroxy, amino, alkoxy, alkylthio, carboxy, cyano, thio, formyl, ester, acyl, thioacyl, amido, sulfonamido, carbamate, phosphine oxide, phosphine sulphide and the like; and
each R is independently selected from the group consisting of —H, alkyl, aryl or heteroaryl (for example substituted or unsubstituted C1-C20 or even C1-C10 alkyl).

The ring system Q acts to bridge between the donor and acceptor moieties. The ring system Q includes at least two rings fused together. The at least two fused together rings may be six membered and/or five membered rings.

Examples of ring systems Q having both five and six membered rings include substituted and unsubstituted fluorene, dibenzothiophene, dibenzofuran, dibenzoselenophene and benzo[1,2-b:4,5-b′] dithiophene ring systems.

Examples of ring systems Q having six membered rings include substituted and unsubstituted aromatic hydrocarbons having fused benzene rings. Such ring systems Q may include substituted or unsubstituted naphthalene, anthracene, phenanthrene and pyrene ring systems. Other polycyclic aromatic ring systems having fused benzene rings are contemplated. For example, anthracene and further members of the group of substituted and unsubstituted acenes (polycyclic aromatic hydrocarbons having fused benzene rings in a rectilinear arrangement).

Scheme 2 below shows examples of such ring systems Q, with the name of the parent ring system given beneath each structure. In each case at least one of the substituents Rq will be a donor moiety (D) and at least one of the substituents Rq will be an acceptor moiety (A). Remaining substituents Rq may be H.

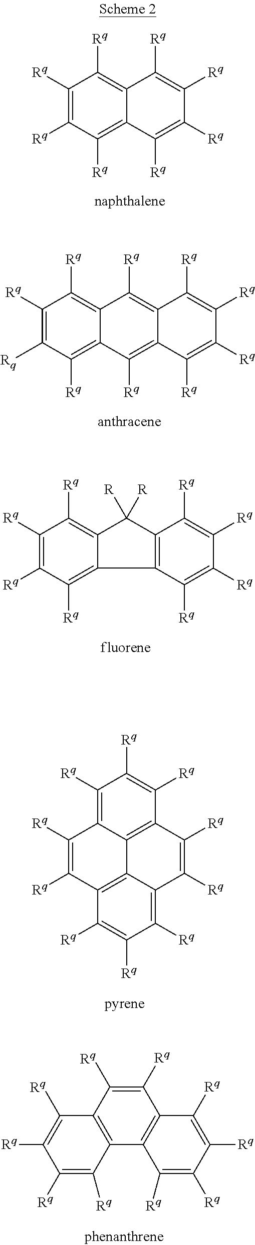

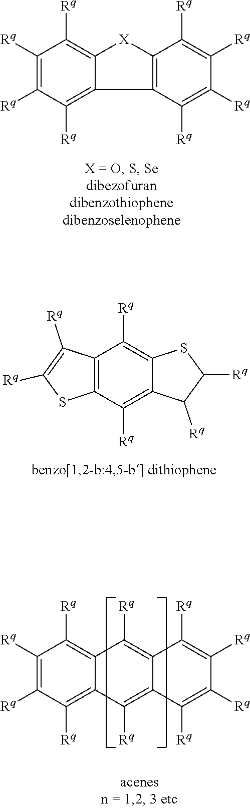

Remaining substituents Rq may be, independently for each occurrence, selected from the group consisting of :
—H, substituted or unsubstituted primary, secondary or tertiary alkyl, that may be cyclic and may be unsaturated (for example C1-C10 or even C1-C4); substituted or unsubstituted aryl or heteroaryl, —CF₃, —OMe, —SF₅, —NO₂, halo (e.g. fluoro, chloro, bromo and iodo), aryl, aryl hydroxy, amino, alkoxy, alkylthio, carboxy, cyano, thio, formyl, ester, acyl, thioacyl, amido, sulfonamido, carbamate, phosphine oxide and phosphine sulfide and the like. For the acene examples n is one or more, for example from 1 to 10. When n is 1 the group Q is an anthracene.

Substituents R on the fluorene may be independently selected from the group consisting of —H, alkyl, aryl or heteroaryl (for example substituted or unsubstituted C1-C20 or even C1-C10). In some examples the substituents R may be donor or acceptor moieties, provided they are weaker than the moieties D and A employed to achieve the TADF effect.

Examples of positioning of Donor (D) and Acceptor (A) groups are shown in Scheme 3 below:

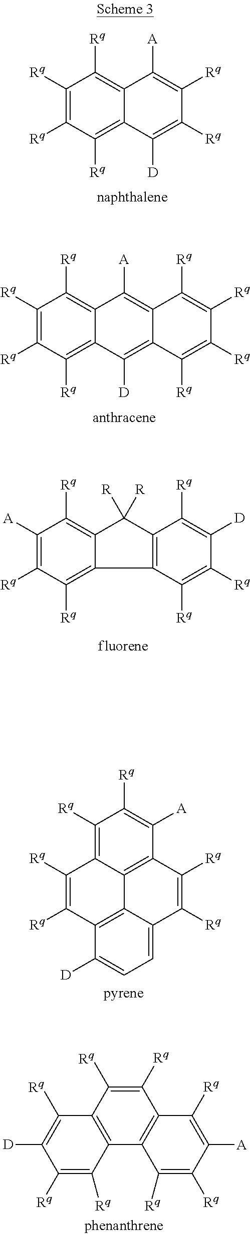

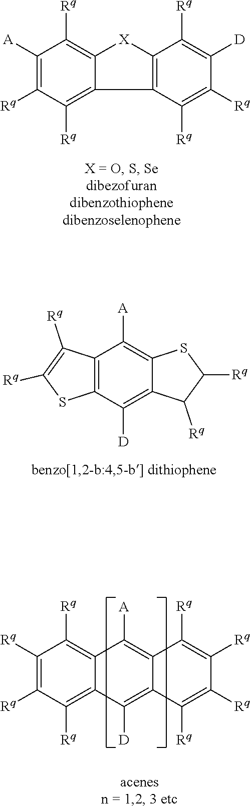

For the acene examples only one each of donor and acceptor groups may be provided, as for the anthracene example shown in Scheme 3, and the other ring(s) present when n=2, 3 etc may have other substituents Rq as discussed above. Thus for example, structures IV, IVa, V, Va and VI (below) are contemplated when n=2 and n=3, as well as structures where A and D are on different rings and/or more than one of each moiety A and/or D is provided.

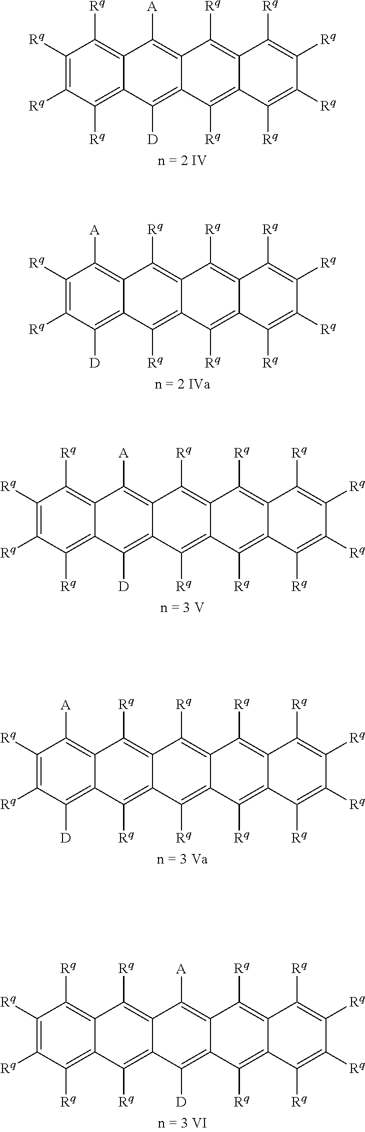

Exemplary organic thermally activated delayed fluorescence (TADF) species according to formula I include the structures VII, VIII IX, and X (below) that make use of —CN as acceptor moieties, anthracene as the ring system Q and, as donor moieties, carbazole, diphenylamine, phenothiazine and phenoxazine.

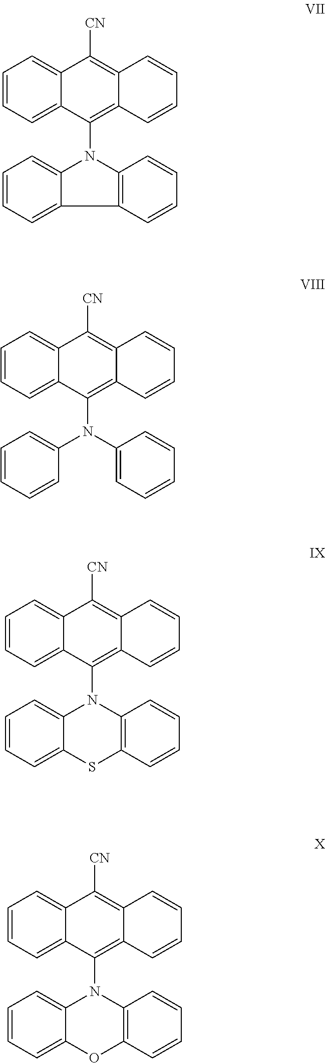 [SMILES: N#Cc1c2ccccc2c(-n2c3ccccc3c3ccccc32)c2ccccc12 ; N#Cc1c2ccccc2c(N(c2ccccc2)c2ccccc2)c2ccccc12 ; N#Cc1c2ccccc2c(N2c3ccccc3Sc3ccccc32)c2ccccc12 ; N#Cc1c2ccccc2c(N2c3ccccc3Oc3ccccc32)c2ccccc12]

The organic thermally activated delayed fluorescence (TADF) species according to formula I may be made in various ways depending on the donor and acceptor groups required and their required positions on the ring system Q. Typically nucleophilic substitution reactions such as nucleophilic aromatic substitution reactions may be employed, together with further manipulations to modify substituents to the desired products as are well known to the skilled person.

For example, and as described with reference to examples hereafter, where an anthracene ring system Q is employed the known 9,10-dibromoanthracene may be utilised as starting material to access TADF species of the invention including cyano as acceptor group. The cyano group itself may be manipulated to provide an oxadiazole acceptor group.

Other means of building or attaching groups to a ring system, especially an aromatic ring system are well known to the skilled person. Similarly, methods for attaching donor moieties D are available to the skilled person. (For example in: Name reactions in heterocyclic chemistry 2005—Jie Jack Li, editor; Wiley; and Strategic Applications of Organic Named Reactions in Organic Synthesis 2005—by Laslo Kurti and Barbara Czako; Academic Press. The content of these documents are incorporated by reference herein).

### BRIEF DESCRIPTION OF THE DRAWINGS

FIG. 1 shows absorption spectra of TADF species;

FIG. 2 shows cyclic voltammagrams of TADF species;

FIG. 3a shows emission spectra of a TADF species; and

FIG. 3b shows emission spectra of a TADF species.

### DETAILED DESCRIPTION OF SOME EMBODIMENTS AND EXPERIMENTAL RESULTS

### General Synthetic Procedures

Commercially available chemicals and reagent grade solvents were used as received. Air-sensitive reactions were performed using standard Schlenk techniques under a nitrogen atmosphere. Freshly distilled anhydrous THF was obtained from a Pure Solv™ solvent purification system (Innovative Technologies). Flash column chromatography was carried out using silica gel (Silia-P from Silicycle, 60 Å, 40-63 μm). Analytical thin-layer-chromatography (TLC) was performed with silica plates with aluminum backings (250 μm with F-254 indicator). TLC visualization was accomplished by 254/365 nm UV lamp. ¹H and ¹³C NMR spectra were recorded on a Bruker Advance AVANCE II 400 spectrometer. Melting points were measured using open-ended capillaries on an Electrothermal melting point apparatus IA9200 and are uncorrected. High-resolution mass spectrometry (HRMS) was performed by the EPSRC National Mass Spectrometry Service Centre (NMSSC), Swansea University. Elemental analyses were performed by Mr. Stephen Boyer, London Metropolitan University.

### Preparation of 9-cyano-10-fluoroanthracene, XI (Scheme 4, Below)

To a solution of 9,10-dibromoanthracene (1.0 g, 3.0 mmol, 1.0 equiv.) in dry THF (20 mL) cooled at −78° C. was added dropwise 1.6 M n-BuLi solution (2.2 mL, 3.6 mmol, 1.2 equiv.). The reaction mixture was stirred at this temperature for 15 min. N-fluorobenzenesulfonimide (0.77 g, 3.0 mmol, 1.0 eq) was added and the mixture was raised to room temperature, followed by stirring for 1 h. The mixture was added to water (25 mL) and extracted by DCM (3×20 mL). The concentrated organic layer was purified by column chromatography using hexane as the eluent. The obtained yellow solid (0.57 g) was dissolved in dry THF (10 mL) cooled at −78° C. 1.6 M n-BuLi solution (1.6 mL, 2.5 mmol, 1.2 equiv.) was dropwise added and the mixture was stirred at this temperature for 15 min. Dry DMF (0.8 mL, 10 mmol, 5 equiv.) was added and the mixture was raised to room temperature followed by additional stirring for 1 h. The mixture was added to 10% HCl (aq) (15 mL) and was extracted with DCM (3×20 mL). The concentrated organic layer was purified by column chromatography using EtOAc:hexane (v/v 1:8) as the eluent. The obtained yellow solid (0.30 g) was mixed with hydroxylamine hydrochloride (0.28 g, 4.1 mmol, 3.0 equiv.) in NMP (10 mL) and heated at 120° C. for 6 h. The mixture was added to water (50 mL) and filter to get the title compound (0.29 g, overall 44%), which was used without further purification.

### General Procedures for Synthesizing Anthracene-Based Emitters

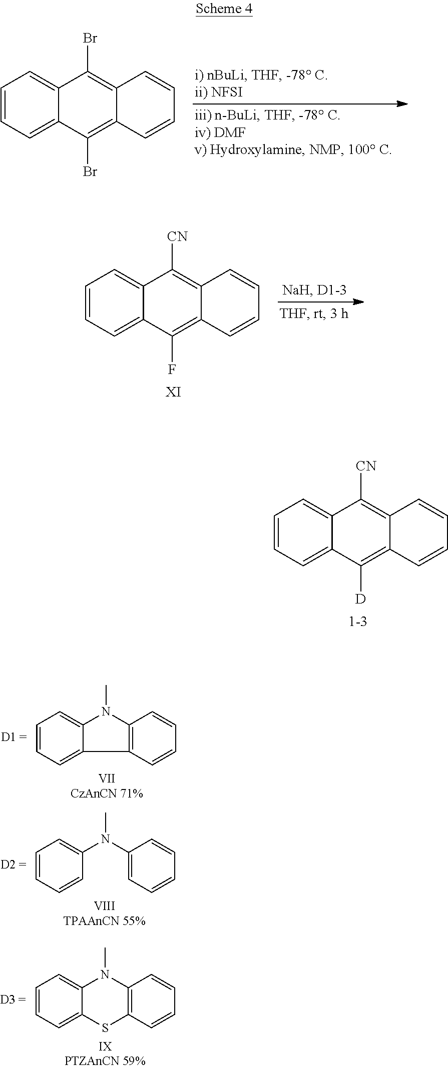

To the corresponding donor amines D1 to D3 (1.2 equiv.) dissolved in dry THF (2 mL) was added NaH (60% in mineral oil, 2.4 equiv.) and the mixture was allowed to stir for 30 min. 9-cyano-10-fluoroanthracene (1.0 equiv.) was added and the mixture was stirred for 3 h. The mixture was added to water (10 mL) and extracted with DCM (3×10 mL). The concentrated organic layer was purified by column chromatography using chloroform:hexane (v/v 1:4). The obtained solid was further recrystallized from DCM/hexane mixture.

### 9-(N-carbazolyl)-10-cyanoanthracene, CZAnCN, VII

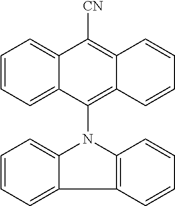 [SMILES: N#Cc1c2ccccc2c(-n2c3ccccc3c3ccccc32)c2ccccc12]

Green solid. Yield: 71%. Mp: 252° C. R_{f}: 0.47 (DCM: hexanes=1:1, silica). ¹H NMR (400 MHz, CD₂Cl₂) δ (ppm): 8.64 (d, J=8.7 Hz, 2 H), 8.35 (dd, J=7.7, 0.9 Hz, 2 H), 7.84-7.80 (m, 2 H), 7.49-7.45 (m, 2 H), 7.41-7.31 (m, 6 H), 6.73 (d, J=7.9 Hz, 2 H) ¹³C NMR (100 MHz, CD₂Cl₂) δ (ppm): 142.5, 135.0, 133.9, 129.4, 129.3, 127.9, 126.4, 125.9, 124.3, 123.4, 120.6, 120.5, 116.7, 110.0, 107.5. HR-MS (ESI): [M+H]⁺ Calculated: (C₂₇H₁₇N₂) 369.1386; Found: 369.1389. Anal. Calcd. for C₂₇H₁₆N₂: C, 88.02; H, 4.38; N, 7.60. Found: C, 87.90; H, 4.26; N, 7.60.

### 9-cyano-10-diphenylaminoanthracene, TPAAnCN, VIII

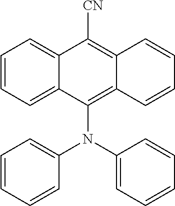 [SMILES: N#Cc1c2ccccc2c(N(c2ccccc2)c2ccccc2)c2ccccc12]

Orange solid. Yield: 55%. Mp: 233° C. R_{f}: 0.48 (EtOAc: hexanes=1:8, silica). ¹H NMR (300 MHz, CDCl₃) δ (ppm): 8.52 (d, J=8.7 Hz, 2 H), 8.22 (d, J=8.8 Hz, 2 H), 7.73-7.68 (m, 2 H), 7.53-7.47 (m, 2 H), 7.24-7.18 (m, 4 H), 7.07-7.04 (m, 4 H), 6.99-6.93 (m, 2 H). ¹³C NMR (76 MHz, CDCl₃) δ (ppm): 147.5, 143.5, 134.7, 130.1, 129.5, 128.9, 127.5, 126.1, 125.4, 122.1, 120.7, 117.3, 105.5. HR-MS (ESI): [M+H]⁺ Calculated: (C₂₇H₁₉N₂) 371.1543; Found: 371.1540. Anal. Calcd. for C₂₇H₁₈N₂: C, 87.54; H, 4.90; N, 7.56. Found: C, 87.44; H, 5.03; N, 7.45.

### 9-cyano-10-(N-phenothiazinyl)anthracene, PTZAnCN, IX

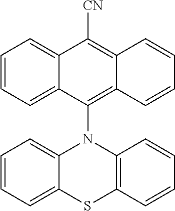 [SMILES: N#Cc1c2ccccc2c(N2c3ccccc3Sc3ccccc32)c2ccccc12]

Red solid. Yield: 59%. Mp: 320° C. R_{f}: 0.43 (EtOAc: hexanes=1:8, silica). ¹H NMR (300 MHz, CDCl₃) δ (ppm): 8.60 (d, J=8.7 Hz, 2 H), 8.44 (d, J=8.8 Hz, 2 H), 7.84-7.78 (m, 2 H), 7.67-7.62 (m, 2 H), 7.11 (dd, J=7.6, 1.5 Hz, 2 H), 6.82 (dd, J=7.5, 1.2 Hz, 2 H), 6.67-6.61 (m, 2 H), 5.70 (dd, J=8.3, 1.1 Hz, 2 H), ¹³C NMR (76 MHz, CDCl₃) δ (ppm): 142.9, 138.6, 134.4, 130.1, 129.4, 128.3, 127.2, 126.8, 126.3, 125.0, 123.1, 120.1, 116.8, 115.9, 107.1. HR-MS (ESI): [M]⁺ Calculated: (C₂₇H₁₆N₂S) 400.1029; Found: 400.1029. Anal. Calcd. for C₂₇H₁₆N₂S: C, 80.97; H, 4.03; N, 6.99. Found: C, 81.05; H, 4.12; N, 7.05.

Photophysical measurements. Optically dilute solutions of concentrations in the order of 10⁻⁵ or 10⁻⁶ M were prepared in HPLC grade solvent for absorption and emission analysis. Absorption spectra were recorded at room temperature on a Shimadzu UV-1800 double beam spectrophotometer. Molar absorptivity values were determined from at least four solutions followed by linear regression analysis. Aerated solutions were bubbled by compressed air for 5 minutes whereas degassed solutions were prepared via five freeze-pump-thaw cycles prior to emission analysis using an in-house adapted fluorescence cuvette, itself purchased from Starna. Steady state emission and excitation spectra and time-resolved emission spectra were recorded at 298 K using an Edinburgh Instruments F980 fluorimeter. Samples were excited at 360 nm for steady state measurements and at 378 nm for time-resolved measurements. Photoluminescence quantum yields for solutions were determined using a dilution method in which four sample solutions with absorbance at 360 nm being ca. 0.10, 0.080, 0.060 and 0.040 were used. Their emission intensities were compared with those of a reference, quinine sulfate, whose quantum yield (ϕᵣ) in 1 N H₂SO₄ was determined to be 54.6% using an absolute method. The quantum yield of sample, ϕₛ, can be determined by the equation ϕₛ=ϕᵣ(Aᵣ/Aₛ)((Iₛ/Iᵣ)(nₛ/nᵣ)², where A stands for the absorbance at the excitation wavelength (λ_{exc}: 360 nm), I is the integrated area under the corrected emission curve and n is the refractive index of the solvent with the subscripts “s” and “r” representing sample and reference respectively. An integrating sphere was employed for quantum yield measurements for thin film samples.

Electrochemistry measurements. Cyclic Voltammetry (CV) analysis was performed on an Electrochemical Analyzer potentiostat model 600D from CH Instruments. Samples were prepared as MeCN solutions, which were degassed by sparging with MeCN-saturated nitrogen gas for 15 minutes prior to measurements. All measurements were performed in 0.1 M MeCN solution of tetrabutylammonium hexafluorophosphate. An Ag/Ag⁺ electrode was used as the reference electrode while a platinum electrode and a platinum wire were used as the working electrode and counter electrode respectively. The redox potentials are reported relative to a saturated calomel electrode (SCE) with a ferrocenium/ferrocene (Fc⁺/Fc) redox couple as the internal standard (0.38 V vs SCE).

X-ray quality crystals of VII, VIII, IX were grown by slow vapour diffusion using DCM as the solvent and diethyl ether as the co-solvent. Their crystal structures show a large torsion angle exists between the donor group and the cyanoanthracene moiety in each of the compounds (68.0°, 80.7° and 85.1° for VII, VIII, IX, respectively). This structural feature, a large dihedral angle between donor and acceptor (—CN in these examples) facilitates a minimization of the exchange integral between the HOMO and the LUMO. This allows well-separated HOMO and LUMO which minimizes the exchange energy, allowing and enhancing the TADF effect.

### Absorption and Electrochemical Properties

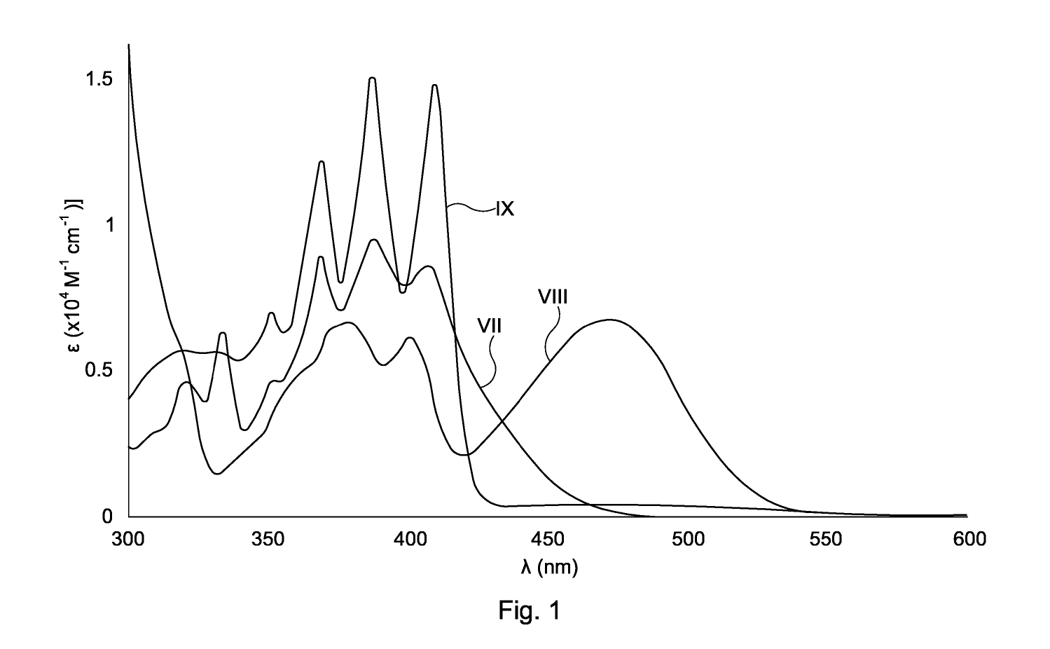

The absorption spectra of VII, VIII, IX were recorded in DCM at room temperature and are shown in FIG. 1. The absorption maxima and corresponding molar absorptivities are summarized in Table 1 (below). There are two major spectral features present. Most distinct, each of the emitters possesses a set of highly structured absorption bands from 370 nm to 412 nm that are characteristic of anthracene. At low energy, each shows a broad charge transfer (CT) absorption that is typical of donor-acceptor dyads. This feature is dominant for TPAAnCN, VIII, at 472 nm, present but blue-shifted as a weak shoulder at 435 nm for CzAnCN, VI, and extremely weak and centred at 480 nm for PTZAnCN, IX. In the latter case, the small absorptivity for this transition is ascribed to the nearly orthogonal orientation the PTZ (phenothiazine) fragment must adopt with respect to the anthracene plan.

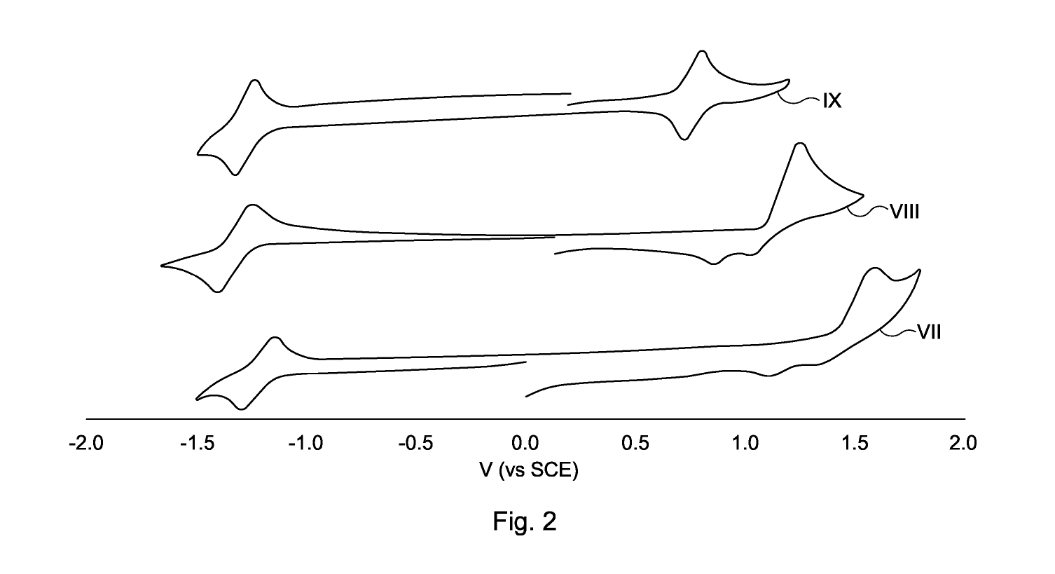

The electrochemical behaviour of VII, VIII, IX was studied by cyclic voltammetry in degassed acetonitrile with tetra-butylammonium hexafluorophosphate as the supporting electrolyte. The cyclic voltammograms (CVs) are shown in FIG. 2 and the data summarized in Table 1. All three emitters exhibit highly reversible reduction waves associated with the cyanoanthracene moiety. They demonstrates highly reversible reductions of the cyanoanthracene moiety.

TABLE 1
Absorption and electrochemical data of VII, VIII, IX.

| | | Electrochemistry^{b} |
|---|---|---|
| Molecule | λ_{abs}^{a} (nm), [ε (×10⁴ M⁻¹ cm⁻¹)] | (eV) |
| CzAnCN, | 310 [0.29], 322 [0.45], 334 [0.63], | HOMO: −5.99 |
| VII | 352 [0.46], 370 [0.87], 390 [0.91], | LUMO: −3.15 |
| | 408 [0.84], 435(sh) [0.31] | ΔE: 2.84 |
| TPAAnCN, | 343(sh) [0.23], 361(sh) [0.47], 373 | HOMO: −5.68 |
| VIII | [0.62], 381 [0.64], 402 [0.58], 472 | LUMO: −3.20 |
| | [0.64] | ΔE: 2.48 |
| PTZAnCN, | 328(br) [0.58], 353 [0.69], 370 | HOMO: −5.19 |
| IX | [1.24], 388 [1.53], 411 [1.46], 480 | LUMO: −3.15 |
| | [0.04] | ΔE: 2.04 |

^{a}in DCM at 298K.
^{b}in MeCN with 0.1M [nBu₄N]PF₆ as the supporting electrolyte and Fc/Fc⁺ as the internal reference (0.38 V vs. SCE). The HOMO and LUMO energies were calculated using the relation E_{HOMO}/_{LUMO} = −(E^{ox}_{pa, 1}/E^{red}_{pc, 1} + 4.8) eV,¹⁷ where E^{ox}ₚₐ and E^{red}_{pc} are anodic and cathodic peak potentials, respectively. ΔE = −(E_{HOMO} − E_{LUMO}).

### Photo Physical Properties

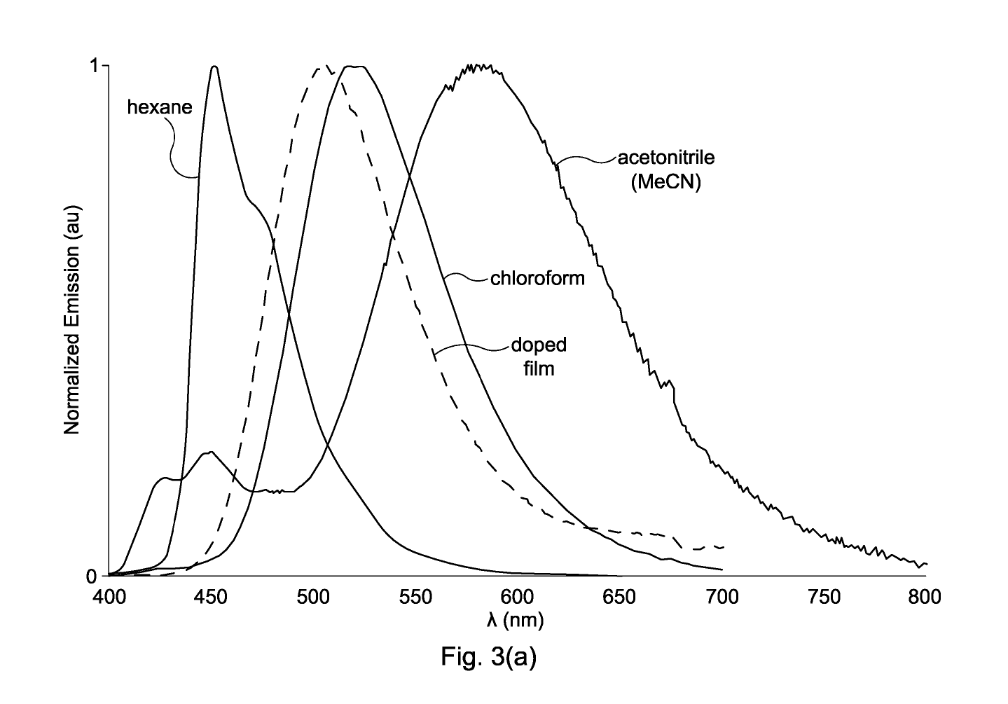

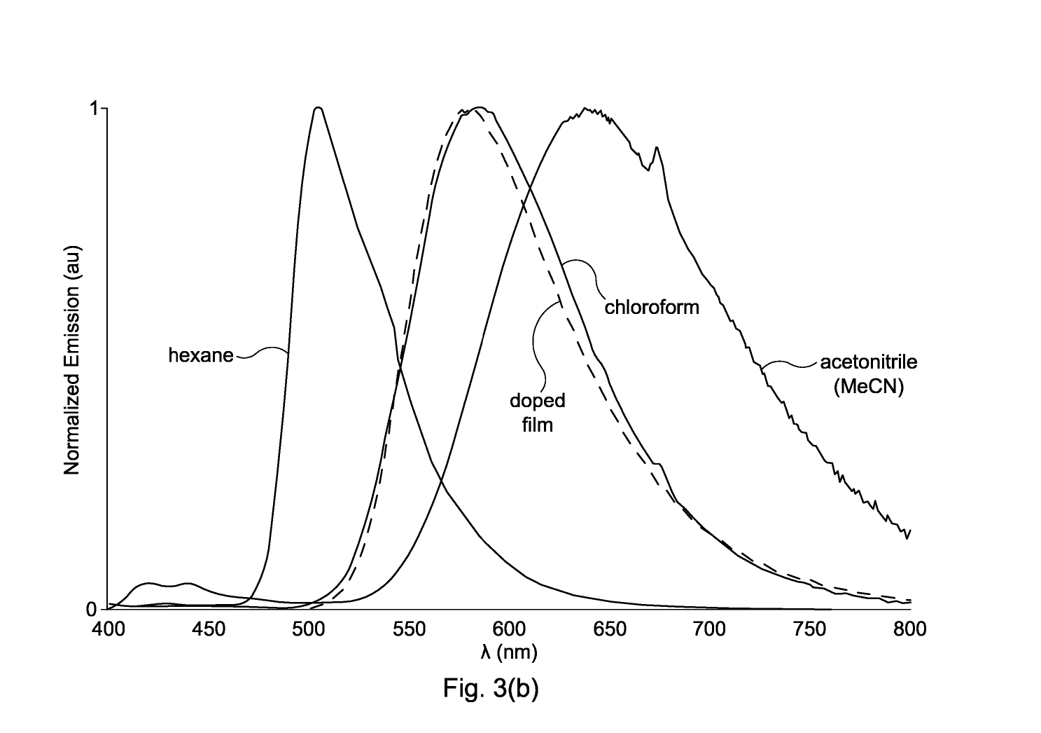

FIG. 3(a) shows emission spectra of VII in solution (hexane, chloroform and acetonitrile) and doped film (10 wt % in PMMA). FIG. 3(b) shows emission spectra of VIII in solution (hexane, chloroform and acetonitrile) and doped film (10 wt % in PMMA). λ_{exc}: 360 nm. Results are shown in Table 2 below for VII, VIII, IX.

TABLE 2
Photophysics data of VII, VIII, IX.

| | | CzAnCN, VII | TPAAnCN, VIII | PTZAnCN, IX |
|---|---|---|---|---|
| Hexane | λₑₘ^{a} (nm) | 452 (49) | 506 (55) | 641 (105) |
| | Φ_{PL}^{b} (%) | 63.0 (27.8) | 69.8 (47.2) | n.d. |
| | Tₑ (ns) | 22.3, 760 | 26.3, 858 | 5.3, 1320 |
| CHCl₃ | λₑₘ^{a} (nm) | 518 (83) | 588 (98) | N/A |
| | Φ_{PL}^{b} (%) | 32.8 (14.7) | 43.2 (37.5) | N/A |
| | Tₑ (ns) | 38.8, 708 | 30.1 | N/A |
| MeCN | λₑₘ^{a} (nm) | 581 (124) | 638 (137) | N/A |
| | Φ_{PL}^{b} (%) | 5.7 (2.9) | 6.7 (6.3) | N/A |
| | Tₑ (ns) | 13.8, 1050 | 8.3 | N/A |
| Thin Film^{c} | λₑₘ^{a} (nm) | 504 (78) | 580 (92) | 674 (212) |
| | Φ_{PL}^{d} (%) | 49.2 (47.0) | 63.4 (62.6) | 1.4 (1.0) |
| | Tₑ (ns) | 21.6, 416 | 29.4, 644 | 8.6, 1032 |

^{a}Emission maxima and full-width at half maximum (FWHM) are reported from degassed solutions.
^{b}0.5M quinine sulfate in H₂SO₄ (aq) was used as the reference (Φ_{PL}: 54.6%). Values quoted are for degassed solutions. Values in parentheses are for aerated solutions.
^{c}Thin films were prepared by spin-coating 10 wt % doped samples in PMMA.
^{d}Values determined using an integrating sphere. Degassing was by N₂ purge.

Both VII and VIII demonstrated positive solvatochromism that is consistent with intramolecular charge transfer nature of the emission. The emission of VIII is more red-shifted than in VII because of the increased donor strength of diphenylamino group compared with carbazole, which is in agreement with electrochemistry results. Compound IX is the reddest emitter in this series because phenothiazine is a very powerful donor. Yet, IX was found to be a low emitter. This may be because of the vanishing transition dipole moment due to loss of electronic communication between the phenothiazine donor and cyanoanthracene moiety, resulting from the near orthogonality between these moieties found in the X-ray study discussed above. This rigidification and larger twisting of the PTZ (phenothiazine) group is distinct from that previously reported for PTZ-containing TADF emitters. Ref X The photoluminescence quantum yields (Φ_{PL}) are largest for VIII and slightly decreased for VII. The Φ_{PL} values decrease with increasing solvent polarity, probably due to increased vibronic coupling between excited state and ground state, i.e the energy-gap law. Upon degassing, the Φ_{PL} values increased for both VII and VIII, suggesting the involvement of the triplet state during emission. Notably, the twofold increase in Φ_{PL} for CzAnCN, VII, upon degassing was significant and present in each of the solvents studied.

In addition, the emission was found to decay with biexponential kinetics. A short nanosecond component and a longer microsecond component are attributed to prompt and delayed fluorescence respectively. This is typical of the TADF phenomenon when present in small molecule organic emitters.

Thin films of VII, VIII and IX were prepared by doping the emitters into PMMA (10 wt %) in DCM, followed by spin-coating this solution on a quartz substrate. PTZAnCN, IX, was found to be low emissive with a Φ_{PL} of only around 1%. Both CzAnCN, VII and TPAAnCN, VIII are bright in the thin film. All three emitters showed both prompt and delayed fluorescence, suggesting the presence of TADF in the solid state.

1. An organic thermally activated delayed fluorescence (TADF) species according to formula I: 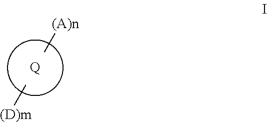
wherein;
Q is an unsaturated carbocyclic or heterocyclic ring system including at least two rings fused together;
each A is an acceptor moiety;
each D is a donor moiety; and
n and m are at least 1.

2. The organic thermally activated delayed fluorescence (TADF) species of claim 1 wherein the ring system Q includes at least one polyunsaturated ring.

3. The organic thermally activated delayed fluorescence (TADF) species of claim 1 wherein the ring system Q includes at least one benzene ring fused to at least one other ring.

4. The organic thermally activated delayed fluorescence (TADF) species of claim 1 both the at least two rings fused together in ring system Q are aromatic and/or heteroaromatic rings.

5. The organic thermally activated delayed fluorescence (TADF) species of claim 1 wherein the ring system Q is an annelated benzene or annelated heteroarene ring system.

6. The organic thermally activated delayed fluorescence (TADF) species of claim 1 wherein donor (D) and acceptor (A) moieties are positioned on the same ring of ring system Q.

7. The organic thermally activated delayed fluorescence (TADF) species of claim 1 wherein donor (D) and acceptor (A) moieties are positioned para to each other on a benzene ring.

8. The organic thermally activated delayed fluorescence (TADF) species of claim 1 wherein acceptor moieties (A) are selected from the group consisting of: cyano (—CN), ketone, esters, amides, aldehydes, sulfones, sulfoxides, phosphine oxides ketones, esters, amides, aldehydes, sulfones, sulfoxides, phosphine oxides and substituted and unsubstituted pyrimidine, pyrazine, 1,2,4-triazole, 1,3,5 triazine and 1,3,4 oxadiazole moieties.

9. The organic thermally activated delayed fluorescence (TADF) species of claim 8 wherein at least one acceptor moiety is according to one of formulas II, III and IIIa. 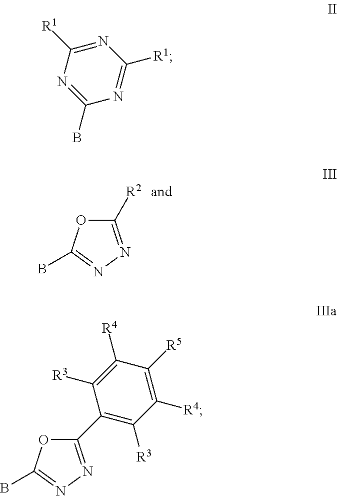
wherein —B represents the bonding position to ring system Q;
—R² represents a substituted or unsubstituted primary, secondary or tertiary alkyl, that may be cyclic and may be unsaturated (for example C1-C10 or even C1-C4); and wherein groups R¹, R³, R⁴ and R⁵ are, independently for each occurrence selected from the group consisting of:
—H, substituted or unsubstituted primary, secondary or tertiary alkyl, that may be cyclic and may be unsaturated (for example C1-C10 or even C1-C4); substituted or unsubstituted aryl or heteroaryl, —CF₃, —OMe, —SF₅, —NO₂, halo, aryl hydroxy, amino, alkoxy, alkylthio, carboxy, cyano, thio, formyl, ester, acyl, thioacyl, amido, sulfonamido, carbamate, phosphine oxide and phosphine sulphide.

10. The organic thermally activated delayed fluorescence (TADF) species of claim 1 wherein donor moieties D are selected from the group consisting of: 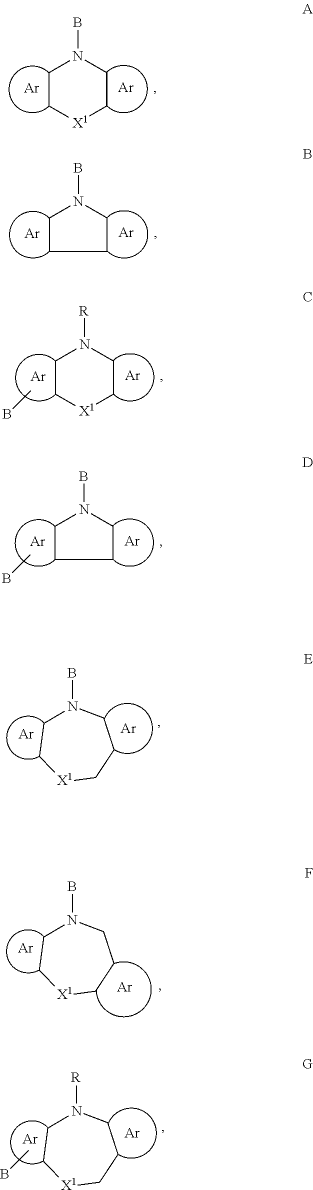 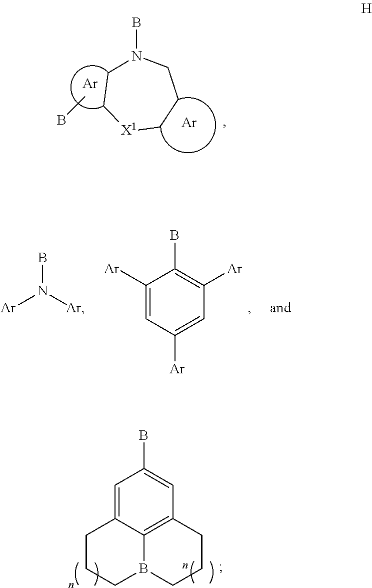
wherein —B represents the bonding position to ring system Q, that is para to the nitrogen in structures C, D, G and H;
X¹ is selected from the group consisting of O, S, NR, SiR₂, PR and CR₂;
each R is independently selected from the group consisting of —H, alkyl, aryl or heteroaryl (for example substituted or unsubstituted C1-C20 or even C1-C10 alkyl);
each Ar is independently for each occurrence selected from the group consisting of substituted or unsubstituted aryl or heteroaryl; and 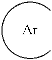
represents, independently for each occurrence a substituted or unsubstituted aryl or heteroaryl ring fused to the central ring of structures A, B, C, D, E or F; for example a five or a six membered substituted or unsubstituted aryl or heteroaryl ring; and
n ( ) indicates the optional presence of saturated —CH₂— groups in the rings annelated to the benzene ring, wherein n is independently for each occurrence, 0, 1, or 2.

11. The organic thermally activated delayed fluorescence (TADF) species of claim 1 wherein donor moieties D are selected from the group consisting of: 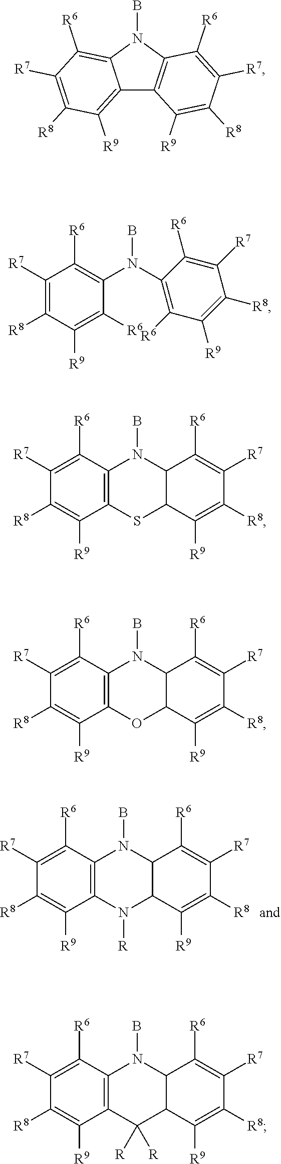
wherein —B represents the bonding position to ring system Q;
each group R⁶, R⁷, R⁸ and R⁹ is, independently for each occurrence, selected from the group consisting of —H, substituted or unsubstituted primary, secondary or tertiary alkyl, that may be cyclic and may be unsaturated (for example C1-C10 or even C1-C4); substituted or unsubstituted aryl or heteroaryl, —CF₃, —OMe, —SF₅, —NO₂, halo (e.g. fluoro, chloro, bromo and iodo), aryl, aryl hydroxy, amino, alkoxy, alkylthio, carboxy, cyano, thio, formyl, ester, acyl, thioacyl, amido, sulfonamido, carbamate, phosphine oxide and phosphine sulphide; and
each R is independently selected from the group consisting of —H, alkyl, aryl or heteroaryl (for example substituted or unsubstituted C1-C20 or even C1-C10 alkyl).

12. The organic thermally activated delayed fluorescence (TADF) species of claim 1 wherein the ring system Q is selected from the group consisting of: 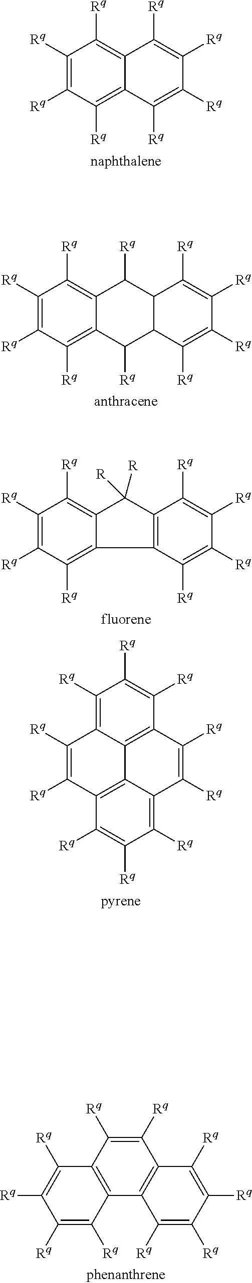 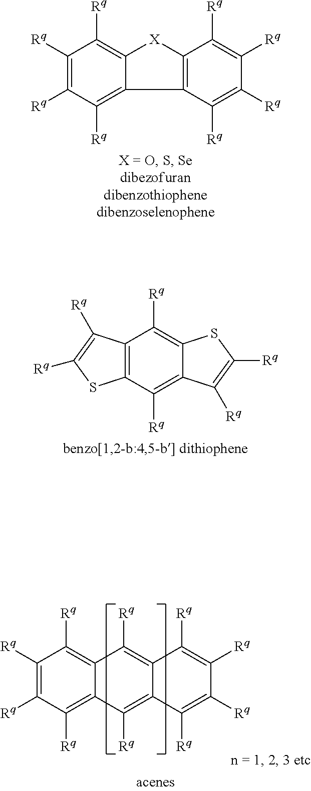
wherein at least one of the substituents Rq is a donor moiety (D) and at least one of the substituents Rq is an acceptor moiety (A);
remaining substituents Rq are, independently for each occurrence, selected from the group consisting of:
—H, substituted or unsubstituted primary, secondary or tertiary alkyl, that may be cyclic and may be unsaturated (for example C1-C10 or even C1-C4); substituted or unsubstituted aryl or heteroaryl, —CF₃, —OMe, —SF₅, —NO₂, halo), aryl, aryl hydroxy, amino, alkoxy, alkylthio, carboxy, cyano, thio, formyl, ester, acyl, thioacyl, amido, sulfonamido, carbamate, phosphine oxide and phosphine sulphide; and
n is one or more.

13. The organic thermally activated delayed fluorescence (TADF) species of claim 12 wherein n is from 1 to 10.

14. The organic thermally activated delayed fluorescence (TADF) species of claim 12 wherein substituents R on the fluorene are independently selected from the group consisting of —H, alkyl, aryl or heteroaryl (for example substituted or unsubstituted C1-C20 or even C1-C10).

15. The organic thermally activated delayed fluorescence (TADF) species of claim 1 selected from the group consisting of:

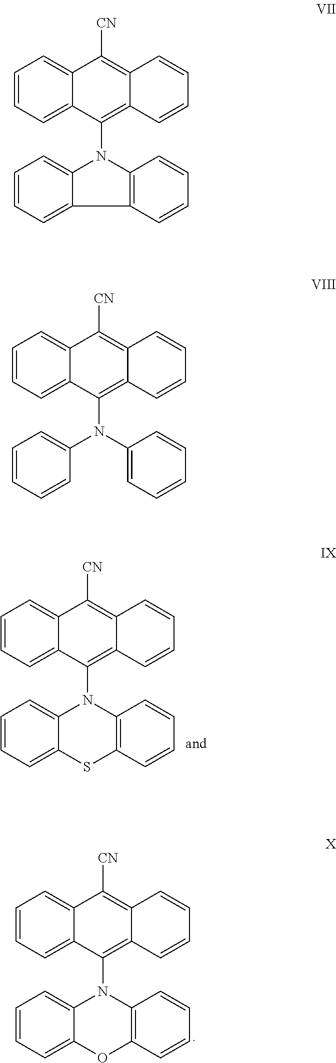 [SMILES: N#Cc1c2ccccc2c(-n2c3ccccc3c3ccccc32)c2ccccc12 ; N#Cc1c2ccccc2c(N(c2ccccc2)c2ccccc2)c2ccccc12 ; N#Cc1c2ccccc2c(N2c3ccccc3Sc3ccccc32)c2ccccc12 ; N#Cc1c2ccccc2c(N2c3ccccc3Oc3ccccc32)c2ccccc12]

16. A light emitting device comprising the organic thermally activated delayed fluorescence (TADF) species of claim 1 as emitter material.

17. The light emitting device of claim 16 wherein the light emitting device is an OLED.

18. The light emitting device of claim 16 wherein the light emitting device is an LEEC.
